(19) United States
(12) Patent Application Publication
(10) Pub. No.: US 2005/0274691 A1
(43) Pub. Date: Dec. 15, 2005

(54) Etch method to minimize hard mask undercut

(76) Inventor: Hyun-Mog Park, Beaverton, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/856,027

(22) Filed: May 27, 2004

(51) Int. Cl. H01L 21/00

(52) U.S. Cl. 216/41; 438/739; 216/79; 438/734

(57) ABSTRACT

A method of etching a semiconductor structure is described herein. The method includes providing a hard mask layer covering a substrate, the hard mask layer having a window to expose a portion of the substrate. Further, a portion of the opening in the substrate is etched generating a hard mask undercut. Then, the hard mask layer is trim-etched to remove the hard mask undercut. Next, the portion of the opening in the substrate is etched for a second time, generating a hard mask undercut for a second time. Trim-etching the hard mask followed by etching the portion of the opening in the substrate is continuously repeated until a predetermined depth of the opening in the substrate is achieved.

### FIELD

The present invention relates to the field of semiconductor processing, and more particularly to the etching process that minimizes a mask undercut.

### BACKGROUND

Decreasing the dimensions of semiconductor devices and increasing the level of their integration are two of the major trends in the current semiconductor device manufacturing field. As a result of these trends, the density of elements forming a semiconductor device continuously increases. The shrinkage of the semiconductor devices down to submicron dimensions requires that the routine fabrication of their elements must also be performed on the submicron level. In addition, to increase the level of the device integration, semiconductor structures forming semiconductor devices may be stacked on top of each other.

Various device components of stacked semiconductor structures may couple to each other by vias, interconnects, trenches, and the like. For example, forming a 3D interconnect so that it electrically bonds the stacked semiconductor structures or components for Micro-Electro-Mechanical Systems (MEMS) applications may require etching a high-aspect ratio, deep opening in a patterned thick semiconductor structure or a substrate and fill it with a conductive material. Further, to ensure a reliable electrical connection, for example, between stacked semiconductor wafers, or between elements of the devices in MEMS applications, a passivation layer, a barrier layer, and a seed conductive layer, such as a copper layer for electroplating deposited to cover the sidewalls of the opening, must be smooth and uniform to allow the conductive material to uniformly fill the opening. For some semiconductor device applications, etching the opening with a depth in the approximate range of 10 um to 100 um is required.

However, deep etching of the opening in the semiconductor substrate results in substantial undercut of the mask covering the semiconductor structure, wherein the mask provides protection for the patterned semiconductor structure from unnecessary etching. FIGS. 1A-1C are illustrations of cross-sectional views of a semiconductor structure at various stages of a prior art process of etching a silicon via. FIG. 1A illustrates a semiconductor structure before the etching process, wherein an oxide hard mask layer 120 with a photoresist layer 130 on the top of the structure covers a silicon substrate 110. The photoresist layer 130 is patterned and has a window 140 to expose a portion of the oxide hard mask 120 covering the silicon substrate 110. FIG. 1B illustrates an etch profile of the semiconductor structure after etching a window 150 in the oxide hard mask 120 to expose the portion of the underlying silicon substrate 110. The window 150 in the oxide hard mask 120 has a tapered profile with a sidewall angle of about 85 degrees relative to the substrate's surface. The tapered profile of the etched window 150 may be a result of lateral etching of the window's sidewalls that may be present in any etching process.

FIG. 1C illustrates an etch profile of the semiconductor structure after etching 25 um deep silicon via 160 in the conventional backend plasma etcher with SF6+O2+CO plasma chemistry. During the plasma etching, the ions 170 bounce from the walls of the tapered oxide hard mask leading to a significant hard mask undercut 180, as illustrated in FIG. 1C. For example, etching a deep 25 um silicon via may result in about 400 nm of the oxide hard mask undercut. FIG. 2 is an illustration of the enlarged cross-sectional view of a semiconductor structure after a deposition of a nitride layer having a thickness of about 1 um using a conventional chemical vapor deposition (CVD) process. Generally, the nitride layer is deposited to passivate the sidewalls of the silicon via before forming a metal interconnect. The hard mask undercut generated during the via etching prevents smooth and uniform deposition of the nitride layer. As illustrated in FIG. 2, the thickness of the nitride layer 210 deposited on top of the oxide hard mask is about 1 um, whereas the thickness of the nitride layer 210 deposited under the oxide hard mask 220 is less than about 300 nm. Generally, the thickness of the nitride layer 210 deposited on the bottom and sidewalls of the via, may be only around one half to one third of the layer deposited of the top of the hard mask 220. Further, the hard mask undercut prevents subsequent smooth, conformal deposition of barrier and seed layers, resulting in voids, especially at the corner of the hard mask 220. The voids in the barrier and seed layers do not allow copper (Cu) or other conductive materials to fill uniformly in the via during the metal interconnect formation. The voids in the metal interconnect jeopardize the device's performance and cause a reliability failure.

One method that is oriented toward reducing the oxide hard mask undercut employs a polymerizing etch process. During this process, a polymer layer is deposited on the sidewalls of the etched silicon substrate to block a lateral component of etching, resulting in reduction of a hard mask undercut. However, this method employs ions with high energy, which may cause damage to a semiconductor structure due to an excessive ion bombardment. Further, the residuals of the polymer layer left on the sidewalls of the etched structure may cause a problem for a subsequent wet cleaning process. More specifically, the residuals of the polymer layer left on the sidewalls may impact the device's performance leading to a device reliability problem.

Another method that attempts to overcome the barrier layer non-uniformity caused by the oxide hard mask undercut uses the atomic layer deposition (ALD) process to deposit a uniform barrier layer. Since, during the ALD process, a material is deposited sequentially one atomic layer after another, this method may be very time-consuming and expensive. In addition, the ALD-based method does not substantially reduce a hard mask undercut caused by etching of a semiconductor structure.

### BRIEF DESCRIPTION OF THE DRAWINGS

FIGS. 1A-1C are illustrations of cross-sectional views of a semiconductor structure at various stages of a prior art process of etching a silicon via.

FIG. 2 is an illustration of the enlarged cross-sectional view of a semiconductor structure after a deposition of a nitride layer, which has a thickness of about 1 um using a conventional chemical vapor deposition (CVD) process.

FIG. 3 illustrates a process of a hard mask trimming, according to one embodiment of the invention.

FIG. 4A is an illustration of a cross-sectional view of a semiconductor structure before an etching process.

FIG. 4B is an illustration of a cross-sectional view of a semiconductor structure after forming a window in a photoresist layer.

FIG. 4C is an illustration of a cross-sectional view of a semiconductor structure after etching a window in a hard mask layer.

FIG. 4D is an illustration of a cross-sectional view of a semiconductor structure after etching a portion of the substrate for the first time according to one embodiment of the invention.

FIG. 4E is an illustration of a cross-sectional view of a semiconductor structure after the mask trim-etching for a first time.

FIG. 4F is an illustration of a cross-sectional view of a semiconductor structure after etching the portion of the substrate for a second time.

FIG. 4G is an illustration of a cross-sectional view of a semiconductor structure after mask trim-etching for a second time.

FIG. 4H is an illustration of a cross-sectional view of a semiconductor structure after etching is completed and a predetermined depth of the opening in the substrate is achieved.

FIG. 4I is an illustration of a cross-sectional view of a semiconductor structure after removal of a photoresist and a hard mask.

FIG. 5 is an illustration of an electronic assembly that contains a 3D interconnect, according to one embodiment of the invention.

FIG. 6 is an illustration of a stacked semiconductor structure that contains a 3D interconnect according to one embodiment of the invention.

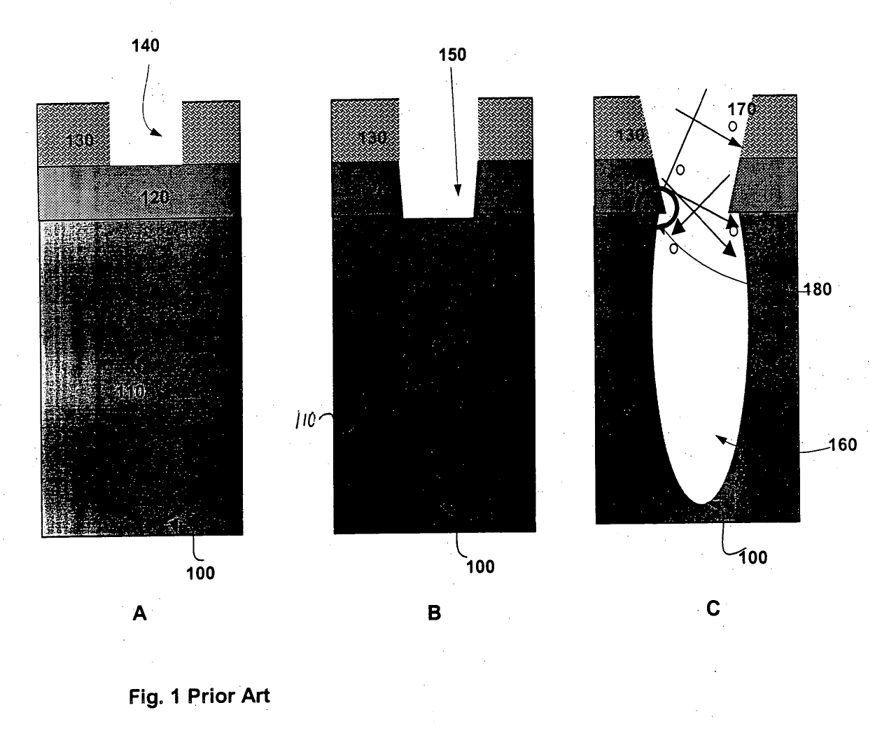

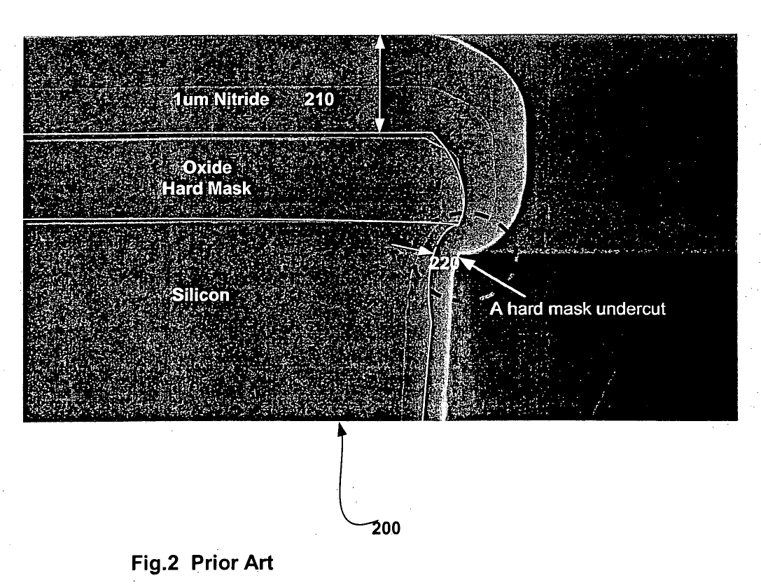

### DETAILED DESCRIPTION

Described herein is a method to minimize a hard mask undercut. In the following description, numerous specific details, such as the specific materials, reactor pressure, temperature, reactor power, etching time, etc. are set forth in order to provide thorough understanding of one or more of the embodiments of the present invention. It will be apparent, however, to one of ordinary skill in the art that the one or more embodiments of the present invention may be practiced without these specific details. In other instances, semiconductor fabrication processes, techniques, materials, equipment, etc., have not been described to avoid unnecessarily obscuring this description. Those of ordinary skill in the art, with the included description, will be able to implement appropriate functionality without undue experimentation.

While certain exemplary embodiments of the invention are described and shown in the accompanying drawings, it is to be understood that such embodiments are merely illustrative and not restrictive of the current invention, and that this invention is not restricted to the specific constructions and arrangements shown and described because modifications may occur to those ordinarily skilled in the art.

Reference throughout the specification to “one embodiment” or “an embodiment” means that a particular feature, structure, or characteristic described in connection with the embodiment is included in at least one embodiment of the present invention. Thus, the appearance of the phrases “in one embodiment” or “in an embodiment” in various places throughout the specification are not necessarily all referring to the same embodiment. Furthermore, the particular features, structures, or characteristics may be combined in any suitable manner in one or more embodiments.

Moreover, inventive aspects lie in less than all the features of a single disclosed embodiment. Thus, the claims following the Detailed Description are hereby expressly incorporated into this Detailed Description, with each claim standing on its own as a separate embodiment of this invention. While the invention has been described in terms of several embodiments, those skilled in the art will recognize that the invention is not limited to the embodiments described, but can be practiced with modification and alteration within the spirit and scope of the appended claims. The description is thus to be regarded as illustrative rather than limiting.

A method to minimize a hard mask undercut during an etching of a high-aspect ratio, deep opening in a semiconductor substrate is described herein. The insertion of one or more trimming etches of a hard mask material into the main etching process of a semiconductor substrate has been demonstrated to minimize the hard mask undercut. The subsequent deposition of substantially smooth, uniform passivation, barrier, and seed layers therefore can be achieved to form, for example, a reliable, high aspect ratio 3D interconnect in the semiconductor structure. Formed by the method described herein, the high aspect ratio 3D interconnect may be a part of an electronic assembly, electrically connecting stacked semiconductor structures.

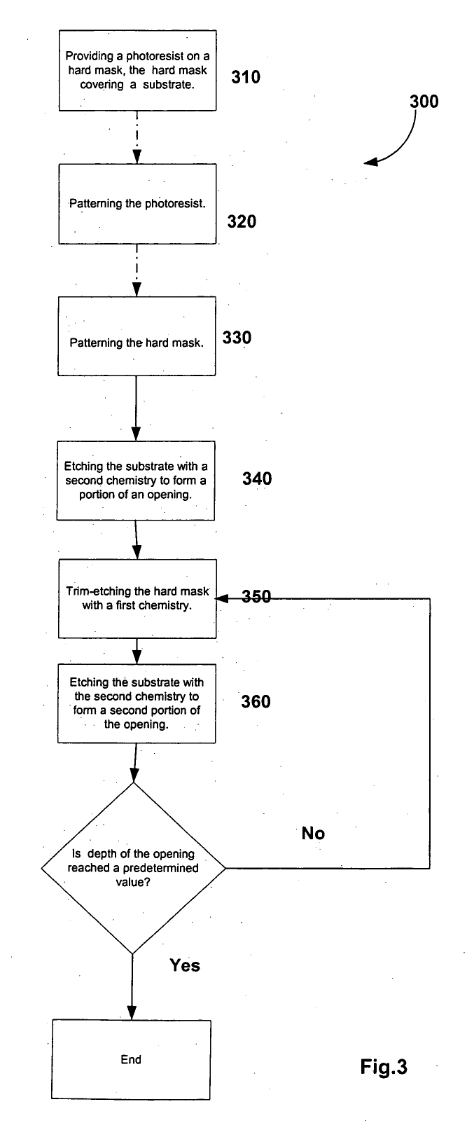

FIG. 3 provides generic illustration of a process 300 of hard mask trimming, according to one embodiment of the invention. The process 300 begins at operation 310 in which a photoresist layer covering the hard mask layer, the hard mask layer covering a substrate is provided. The process 300 continues with operation 320 in which the photoresist layer is patterned to form a window to expose a portion of the hard mask layer. Next, the hard mask layer is patterned to form a window to expose a portion of the substrate during operation 330. Further, operation 340 is performed, in which the exposed portion of the substrate may be etched with a second chemistry to form a portion of an opening in the substrate, wherein the second chemistry is substantially selective to the hard mask and etching the substrate creates a hard mask undercut. Then, the process 300 continues with operation 350, in which the hard mask is trim-etched with a first chemistry to remove the hard mask undercut. Next, operation 360 is performed, in which the substrate is etched with the second chemistry for a second time to form a second portion of the opening in the substrate. Further, if a depth of the opening has not reached a predetermined value, the cycle comprising operations 350 and 360 repeats. If the predetermined depth of the opening has been reached, the etching process ends.

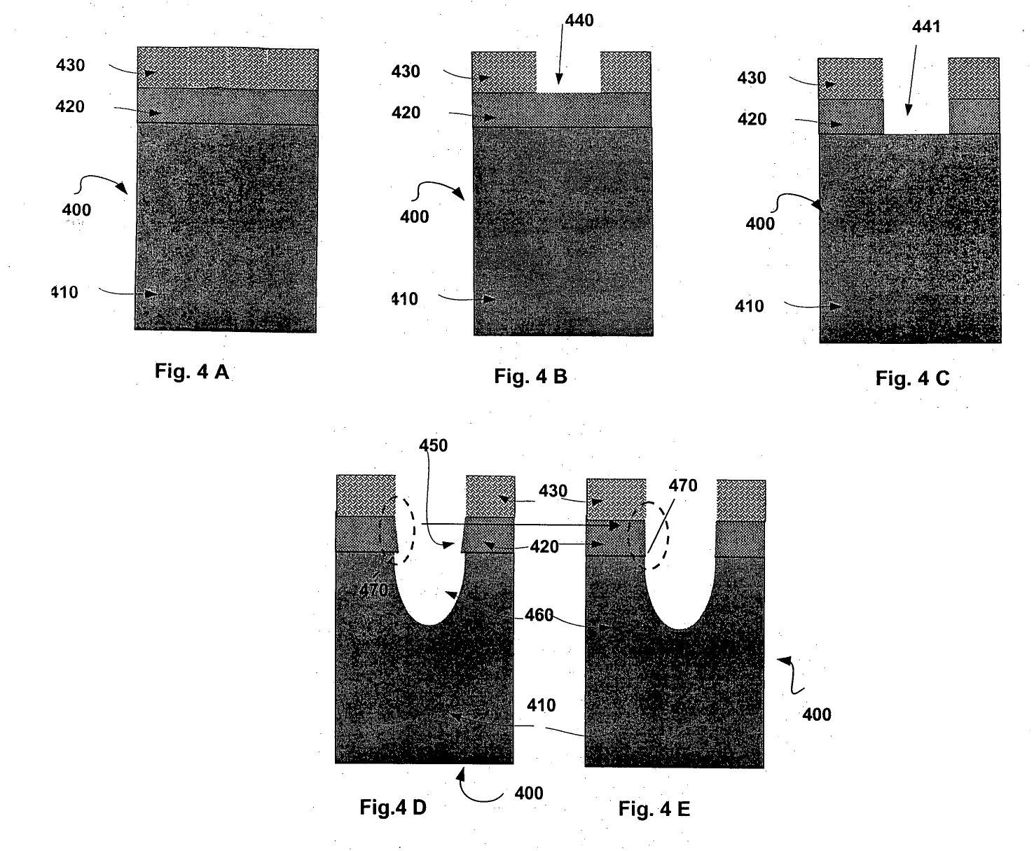

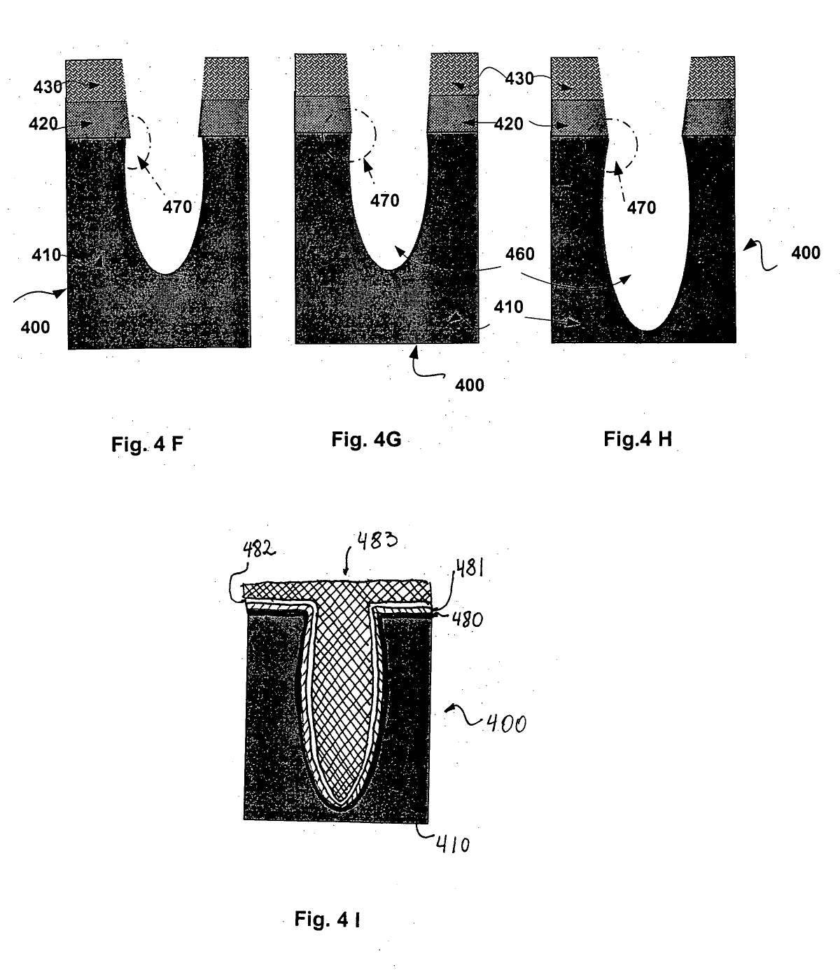

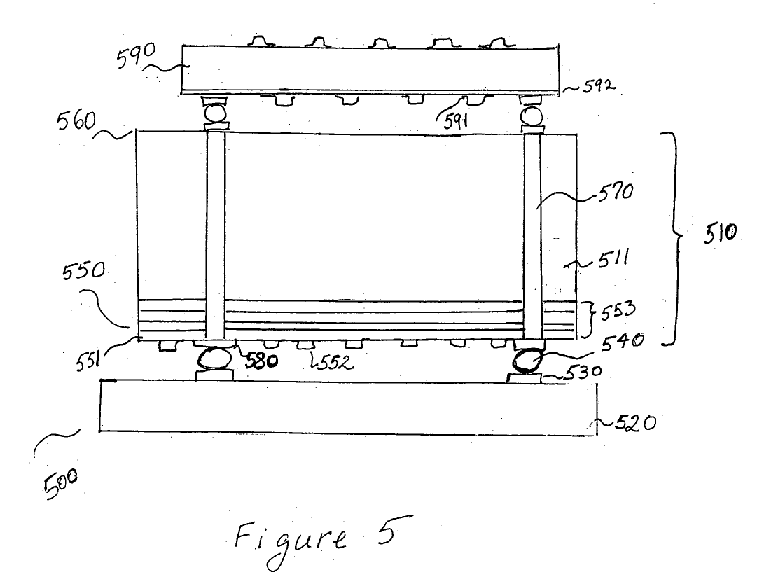

FIGS. 4A to 4I provide more specific illustrations of an embodiment of the invention. FIG. 4A is an illustration of a cross-sectional view of a semiconductor structure before an etching process. The semiconductor structure may comprise a substrate 410 with a hard mask layer 420 covering the substrate 410. Further, a photoresist layer 430 is deposited on top of the hard mask layer 420 covering the substrate 410. The purpose of the photoresist layer 430 is to pattern the underlying hard mask layer 420 and define an opening in the mask layer 420 that may be etched into the substrate 410. Because the photoresist layer 430 may erode during etching of the substrate 410, the hard mask layer 420 is deposited between the substrate 410 and the photoresist layer 430. The purpose of the hard mask layer 420 is to protect specific regions of the substrate 410 covered by the hard mask 420 from unnecessary etching. The substrate 410 may comprise any material to make any of integrated circuits, passive, and active devices. The substrate 410 may include insulating materials that separate such active and passive devices from a conductive layer or layers that are formed on top of them. In one embodiment, the mask layer 420 may be deposited on a backside of the substrate 410, wherein the backside of the substrate 410 may be a non-device side of a semiconductor wafer. In one embodiment, the substrate 410 covered by the hard mask layer 420 may be a monocrystalline silicon. In another embodiment, the substrate 410 covered by the hard mask layer 420 may be an oxide substrate. Further, the hard mask layer 420 may be made of any material that prevents the underlying substrate 410 from unnecessary etching. In one embodiment, the oxide hard mask layer 420 may cover a monocrystalline silicon substrate. In alternate embodiments, any one of a nitride and a silicon carbide hard mask 420 may cover an oxide substrate. The hard mask layer 420 covering the substrate 410 may have a thickness in the approximate range of 1 um to 2 um.

Further, the photoresist layer 430 may be patterned using a conventional photolithographic technique. The technique may include masking the photoresist layer 430, exposing the masked layer 420 to light, and then developing the unexposed portions to remove the portions of the photoresist layer 430 that are exposed to light to form a window 440 in the photoresist layer 430. One having ordinary skill in the art will appreciate that other photoresist techniques may also be used. FIG. 4B is an illustration of a cross-sectional view of a semiconductor structure after the portion of the photoresist layer 430 has been removed to form a window 440.

After forming the window 440 in the photoresist layer 430, the hard mask layer 420 is patterned to define an opening in the substrate 410. Patterning of the hard mask layer 420 is performed by removing the exposed portion of the hard mask layer 420 to expose a portion of the substrate 441 for subsequent etching, as illustrated in FIG. 4C. Next, the exposed portion of the hard mask layer 420 covering the substrate 410 may be removed by etching. In one embodiment, the etching of the exposed portion of the hard mask layer 420 may be a dry etching. In a more specific embodiment, the dry etching may be performed using a conventional reactive ion etching (RIE) technique. To perform reactive ion etching, the semiconductor structure 400 is placed into a plasma reactor, for example, into an electron cyclotron resonance chamber. The plasma reactor produces chemically reactive plasma (e.g., ions) from a gas. In alternate embodiments, the chemically reactive plasma having a chemistry produced, for example, from combinations of each of the gases, such as CF4, C2F6, C4F8, CH2F2, CHF3, CH3F, or SF6, and the like, with the additive gases, such as Ar, O2, and the like, may be used to etch the oxide hard mask material covering the silicon substrate. In other embodiments, the chemistry to etch the silicon carbide or nitride hard mask material covering the oxide substrate may be produced, for example, from a combination of each of the gases, such as CH2F2, CH3F, or CHF3, and the like, with the additive gases, such as Ar, O2, and the like.

An electrical power applied to the reactor (chamber) may affect reactive ion intensity. In one embodiment, the RF power applied to the chamber may be in the approximate range of 500 to 4000 W, the pressure within the chamber may be below 150 mTorr, and the temperature in the chamber may be maintained in the approximate range of 0 to 50 C. In one particular embodiment, to etch the oxide hard mask covering the silicon substrate, the RF power applied to the chamber may be in the approximate range of 3000 W to 4000 W, the pressure within the chamber may be approximately 40 mT, and the temperature is maintained at approximately 15 C.

Next, a portion of the substrate material exposed through a mask window 441 may be removed to form a portion of an opening in the substrate 410. The portion of the substrate material 441 may be removed by etching with a second chemistry having substantially high selectivity to the hard mask material, meaning that the second chemistry predominantly etches the substrate material rather than the hard mask material. In one embodiment, the second chemistry, having the ratio of the etching rates of the substrate 410 to the hard mask layer 420 of approximately 10:1, may be used. In a more specific embodiment, using the RIE technique, the second chemistry comprising, for example, such gases as SF6, CO, and O2 may be used to etch the portion of the silicon substrate covered by the patterned oxide hard mask layer. In one embodiment, the same equipment, for example, a plasma reactor may be used to etch the hard mask layer and the substrate. In one embodiment, the RF power applied to the chamber may be in the approximate range of 500 to 4000W, the pressure within the chamber may be below 150 mT, and the temperature may be maintained in the approximate range of 0-50 C. In one particular embodiment, to etch, for example, the silicon substrate that is covered by the oxide hard mask, the RF power applied to the chamber may be in the approximate range of 500 W to 1000 W, the pressure within the chamber may be below 100 mT and the temperature in the chamber may be approximately 15C.

Generally, etching the substrate 410 to form the portion of the opening 460 is followed by trim-etching of the hard mask layer. FIG. 4D illustrates a semiconductor structure after etching a portion of the opening 460 in the substrate 410 for a first time. In one embodiment, as illustrated in FIG. 4D, a tapered profile of the hard mask window 450, as well as a hard mask undercut 470 having a sharp corner, may be generated as a result of etching the substrate 410. An undercut may be produced, even during a directional (anisotropic) etch, because an isotropic etching component is present, in practice, in any anisotropic etching process. The tapered profile of the hard mask window 450 may be generated, for example, because of the erosion of the photoresist 430 during the substrate etch. In case of dry plasma etching, the hard mask undercut 470 may be generated, for example, because etching ions bounce from the walls of the tapered hard mask window 450. In one embodiment, etching the substrate 410 to form the portion of the opening in the substrate discontinues when a hard mask undercut 470 is generated. In another embodiment, etching the substrate 410 to form the portion of the opening 460 in the substrate 410 discontinues as soon as a predetermined depth of the portion of the opening 460 in the substrate 410 is achieved. In yet another embodiment, etching the substrate to form the portion of the opening 460 in the substrate 410 discontinues when a predetermined amount of time is expired.

Next, the hard mask corner 470 is trimmed away for a first time to produce smooth vertical sidewalls of the opening 460 in the substrate 410, resulting in a substantial reduction of the hard mask window 450 tapering and undercut. FIG. 4E is an illustration of a cross-sectional view of a semiconductor structure after hard mask trimming for a first time. As illustrated in FIG. 4E, the hard mask corner 470 is substantially reduced, resulting in smooth vertical sidewalls of the opening 460 in the substrate 410. Trimming the mask is performed by etching the mask with the first chemistry having substantially high selectivity to the substrate material. More specifically, a ratio of the etch rates of the hard mask layer 420 relative to the underlying substrate 410 may be approximately 10:1. In one embodiment, a RIE technique may be used for trim-etching the hard mask layer 420.

In one embodiment, patterning the hard mask layer, etching the opening in the substrate covered by the patterned hard mask and trim-etching of the hard mask to remove the hard mask undercut may be performed in the same plasma reactor using the RIE technique. For example, after etching the portion of the exposed mask with the first chemistry to form a window in the mask and define the opening size in the substrate, the first chemistry is purged from the reactor. Then, the second chemistry to etch the substrate to form a portion of the opening in the substrate is introduced into the reactor. After forming the portion of the opening in the substrate, the second chemistry is purged from the reactor. Then, the first chemistry to trim-etch the hard mask is introduced into the reactor.

After the hard mask undercut 470 is removed, the substrate 410 may be etched for a second time, further increasing the depth of the opening in the substrate 410. In one embodiment, etching the substrate 410 for a second time to form a second portion of the opening in the substrate 410 discontinues when a hard mask undercut 470 is generated for a second time. In more specific alternate embodiments, etching the substrate 410 for a second time to form a second portion of the opening in the substrate 410 discontinues when any one of a predetermined depth of a second portion of the opening in the substrate 410 is achieved or a predetermined etching time is expired. FIG. 4F is an illustration of a cross-sectional view of a semiconductor structure after etching a portion of the substrate 410 for a second time. As illustrated in FIG. 4F, the hard mask undercut 470, having sharp corners as well as the tapered profile of the hard mask 420 window, is generated during the substrate etch for a second time. The hard mask undercut 470 is trimmed away for a second time by trim-etching of the hard mask 420. FIG. 4G is an illustration of a cross-sectional view of a semiconductor structure after mask trim-etching for a second time. In one embodiment, the cycle of trim-etching of the hard mask layer 420 to remove the hard mask undercut 470 followed by etching of the substrate 410 to form the second portion of the opening 460 in the substrate 410 is continuously repeated until a predetermined depth of the opening in the substrate 410 is achieved.

FIG. 4H is an illustration of a cross-sectional view of an opening in the substrate 460 having the predetermined depth after completing the etching process. As illustrated in FIG. 4H, smooth sidewalls of the opening 460 in the substrate 410 with minimal hard mask undercut 470 are produced. Generally, the opening 460 may have a substantially high aspect ratio of depth to diameter, for example, in the approximate range of 10:1 to 100:1. In one embodiment, the diameter of the opening in the substrate 460 covered by the hard mask 420 may be in the approximate range of 1 um to several tens of um, whereas the depth of the opening 460 in the substrate 410 may be in the approximate range of 25 um to 100 um.

In one specific embodiment, the oxide hard mask etch followed by 5 cycles comprising etching the portion of the silicon substrate and trim-etching of the oxide hard mask may result in about 6 times reduction of the oxide hard mask undercut. More specifically, by using the method described herein, for example, to etch a 25 um deep silicon via having the diameter of about 5 um, the oxide hard mask undercut is reduced from about 400 nm to about 70 nm.

For the reasons described above, trim-etching of the hard mask is easy to implement into the main process of etching the opening in the substrate, since it does not require modification of the latter. In addition, trim-etching the hard mask does not impact the subsequent wet cleaning process of the semiconductor structure.

Further, each etching of the substrate by the second chemistry may take an A amount of time and each subsequent trim-etching of the hard mask may take a B amount of time. In one embodiment, the B amount of time is substantially shorter than A amount of time. In a more specific embodiment, each trim-etching of the oxide hard mask may take about 10 sec or less, whereas each etching of the silicon substrate may take about 2 minutes. In one embodiment, the trim-etch of the oxide hard mask covering the silicon substrate may generate ripples on the sidewalls of the opening in the silicon substrate. However, the ripples do not impact the subsequent processing of the semiconductor structure. In addition, for example, during the deep silicon via etch, the oxide hard mask trim-etch may increase the via's diameter by less than 5%. In one embodiment, for example, the oxide hard mask trim-etch increases the diameter of the silicon via from about 5 um to about 5.3 um. In one embodiment, to form a 3D interconnect, after the opening in the substrate (e.g., a via) has been formed according to the method described above, portions of the hard mask and photoresist layers covering the semiconductor substrate may be removed using corresponding chemistries.

FIG. 4I is an illustration of a cross-sectional view of a semiconductor structure after removal of the portions of the photoresist and hard mask layers and subsequent deposition of a passivation layer 480, barrier layer 481 and a seed layer 482, according to one embodiment of the invention. The smooth and uniform passivation layer 480 may be deposited to passivate sidewalls and a bottom of the opening in the substrate. The chemical vapor deposition (CVD) process may be used to deposit the passivation layer 480 on the sidewalls and bottom of the opening. In one embodiment, the passivation layer 480 is a nitride layer having a thickness of about 1 to 2 um. Further, a smooth and uniform barrier layer 481 and seed layer 482 may be deposited to cover the passivation layer 480. Typically, a barrier layer 481 and seed layer 482 are deposited to provide mechanical and electrical foundation layers on which substantially high quality bulk conductive material 483 may be electroplated. More specifically, the barrier layer 481 may be deposited to prevent diffusion of the conductive material that fills the interconnect, through the sidewalls and bottom of the via. The physical vapor deposition (PVD) may be used to deposit the barrier layer 481 and seed layer 482. In one embodiment, the barrier layer 481 may comprise, for example, a Tantalum (Ta) and Tantalum Nitride (TaN), and the seed layer 482 may comprise, for example, copper. A smooth and uniform seed layer 482 provides a foundation for a void-free conductive filling 483 of the via, resulting in the formation of a reliable 3D interconnect. Filling of the via by a conductive material, for example, copper may be performed using, for example, an electroplating technique. Unnecessary portions of the seed layer 482 and barrier layer 481 covering the surface of the semiconductor structure may be removed by, for example, chemical polishing, to prevent shorts between vias and other elements of the semiconductor structure. Thus, a reliable, void-free 3D interconnect has been demonstrated to be produced.

The high-aspect ratio 3D interconnect formed with the method described herein may be a part of an electronic assembly, wherein the 3D interconnect electrically connects stacked semiconductor structures with each other. An exemplary embodiment of the electronic assembly 500 is illustrated in FIG. 5. The electronic assembly 500 may comprise a first semiconductor wafer 510 placed on a printed circuit board (PCB) 520. The PCB 520 having rising conductive pads 530 with solder balls 540 to provide an electrical connection between the PCB 520 and the semiconductor wafer 510. The first semiconductor wafer 510 comprises a front side 550 and a backside 560. The front side 550 of the first semiconductor wafer 510 may comprise one or more of a first integrated circuit layer 551 and a layer having individual micro devices 552 formed on a multilayered structure 553. The back side 560 of the first semiconductor wafer 510 may comprise a silicon substrate 511 with a 3D interconnect 570 formed from the back side 560 of the wafer 510 using the method described herein. As illustrated on FIG. 5, the 3D interconnect 570 extends through the silicon substrate 511 and all layers of the first semiconductor wafer 510 to the front side 550 of the wafer 510. One end of the 3D interconnect 570 is electrically connected to the PCB 520 through metallic bumps 580 formed at both ends of the 3D interconnect 570, solder balls 540 and conductive pads 530. As a result, the appropriate conductive surface areas of the front side 550 of the wafer 510 and the PCB 520 are electrically connected to the appropriate conductive surface areas of the back side 560 of the wafer 510 through the 3D interconnect 570. In addition, the other end of the 3D interconnect 570, in the same manner, may be electrically connected, for example, to a second integrated circuit layer 592, which may be incorporated into the front side 591 of a second semiconductor wafer 590, which may be stacked above the first semiconductor wafer 510. As a result, the direct electrical connection between appropriate conductive surface areas of stacked semiconductor wafers and printed circuit board may be established through the 3D interconnect.

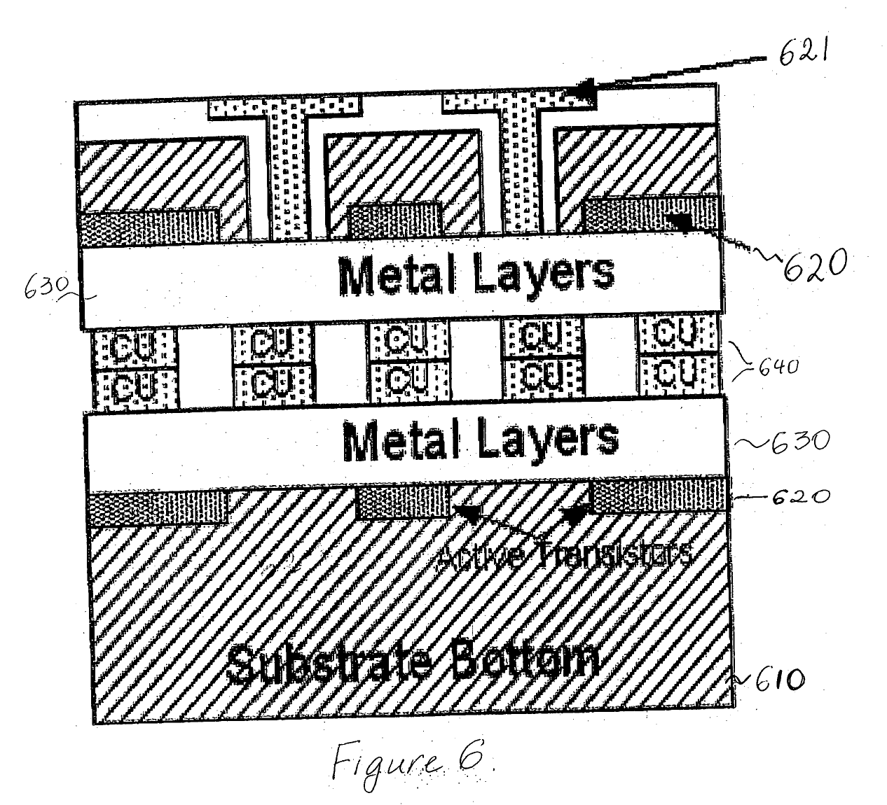

Another exemplary embodiment of a 3D interconnect formed in a stacked semiconductor structure 600, using a method described herein, is illustrated in FIG. 6. The stacked semiconductor structure 600 may comprise a first wafer 610 having micro devices 620, for example, active transistors buried by one or more of lower metal layers 630. The one or more lower metal layers 630 provide coupling between the micro devices 620 of the first wafer 610. Further, a second wafer 650 may be stacked above the first wafer 610. The lower side of the second wafer 650 comprises micro devices 620, for example, active transistors, wherein the micro devices 620 may be coupled to each other by one or more underlying lower metal layers 630. The appropriate areas of the first wafer 610 may be electrically connected to the appropriate areas of the second wafer 650 by contact units 640 sandwiched between one and more of lower metal layers 630 of the first and second wafers 610, 650. A 3D interconnect 621 used to electrically connect the stacked semiconductor structure 600 to a printed circuit board (PCB), which may be a motherboard of a computer, extends through the second wafer 650 from the surface of the upper side of the second wafer 650 down to one or more metal layers 630. Thus, the 3D interconnect 621 may establish the direct electrical connection between the PCB, appropriate upper surface areas of the second wafer 650, and the appropriate areas of the first semiconductor wafer 610 of the stacked semiconductor structure 600.

1. A method comprising:
providing a mask on a material, the mask having a window to expose the underlying material;
forming a portion of an opening in the material;
trimming the mask; and
forming a second portion of the opening in the material.

2. The method of claim 1 further comprising:
trimming the mask for a second time; and
forming a third portion of the opening in the material.

3. The method of claim 2 comprising:
trimming the mask for a third time; and
forming a fourth portion of the opening in the material.

4. The method of claim 1, wherein trimming the mask followed by forming the second portion of the opening in the material are continuously repeated until a predetermined depth of the opening in the material is achieved.

5. The method of claim 4, wherein forming the portion of the opening in the material comprises etching the material with a second chemistry, the second chemistry having a substantially high selectivity to the mask and trimming the mask comprises etching the mask with a first chemistry, the first chemistry having a substantially high selectivity to the material.

6. A method comprising:
(a) providing a photoresist layer on a mask layer, wherein the mask layer covers a substrate;
(b) forming a window in the photoresist layer to expose a portion of the mask layer;
(c) removing the portion of the mask layer to expose the underlying substrate;
(d) forming a portion of an opening in the substrate, wherein forming the portion of the opening in the substrate generates a mask undercut;
(e) trimming the mask layer to remove the mask undercut; and
(f) forming a second portion of an opening in the substrate, wherein forming the second portion of the opening in the substrate generates the mask undercut.

7. The method of claim 6, wherein (e) and (f) are continuously repeated in sequence until a predetermined depth of the opening in the substrate is achieved.

8. The method of claim 7, wherein the mask layer is an oxide hard mask layer and the substrate comprises silicon.

9. The method of claim 8, wherein each of (d) and (f) comprises etching the substrate with a second chemistry and (e) comprises trim-etching the mask with a first chemistry.

10. The method of claim 9, wherein (c) is performed by etching the mask layer using the first chemistry.

11. The method of claim 10, wherein etching comprises a reactive ion etching process.

12. The method of claim 11, wherein the first chemistry has a substantially high selectivity to the substrate and the second chemistry has a substantially high selectivity to the hard mask layer.

13. A method to form a 3D interconnect comprising:
providing a substrate;
forming a hard mask layer on the substrate;
forming a photoresist layer on the hard mask layer;
patterning the photoresist layer to form a window to expose a portion of the hard mask;
patterning the hard mask layer to form a second window to expose a portion of the substrate;
etching the portion of the substrate to form a portion of an opening in the substrate, wherein etching the portion of the substrate generates a hard mask undercut;
trim-etching the hard mask to remove the hard mask undercut;
etching the portion of the substrate to form a second portion of an opening in the substrate, wherein etching the portion of the substrate generates a hard mask undercut;
repeating trim-etching the hard mask followed by etching the portion of the substrate continuously in sequence until a predetermined depth of the opening in the substrate is achieved;
depositing a passivation layer to passivate a sidewall of the opening in the substrate;
depositing one or more of a barrier layer and a seed layer on top of the passivation layer; and
filling the opening in the substrate by a conductive material.

14. The method of claim 13, wherein etching the portion of the substrate is performed using a second chemistry and trim etching of the hard mask layer is performed using a first chemistry.

15. The method of claim 14, wherein the first chemistry is substantially selective to the substrate and the second chemistry is substantially selective to the hard mask.

16. The method of claim 15, wherein patterning the hard mask layer is performed using the first chemistry.

17. The method of claim 16, wherein the hard mask layer is an oxide hard mask layer and the substrate comprises silicon.

18. The method of claim 17, wherein the passivation layer comprises a nitride, the barrier layer comprises a tantalum, and the seed layer comprises a copper.

19. The method of claim 17, wherein etching the portion of the substrate and trim-etching the hard mask layer are performed in the same chamber using a reactive ion etching process.

20. The method of claim 19, wherein trim-etching the hard mask layer takes substantially shorter time relative to etching the portion of the substrate.
